(19) United States
(12) Patent Application Publication
(10) Pub. No.: US 2025/0022794 A1
(43) Pub. Date: Jan. 16, 2025

(54) SEMICONDUCTOR DEVICE

(71) Applicant: Renesas Electronics Corporation, Tokyo (JP)

(72) Inventors: Takayuki IGARASHI, Tokyo (JP); Yasutaka NAKASHIBA, Tokyo (JP)

(21) Appl. No.: 18/768,246

(22) Filed: Jul. 10, 2024

(30) Foreign Application Priority Data
Jul. 11, 2023 (JP) 2023-113612

(51) Int. Cl. H01L 23/522; H01L 27/02

(52) U.S. Cl. CPC H01L 23/5225; H01L 23/5226; H01L 27/0207

(57) ABSTRACT

A semiconductor device includes a semiconductor substrate, a first coil, a second coil, a third coil, and a fourth coil, an insulating layer, and a first shield. The semiconductor substrate has a device region and a peripheral region. The peripheral region is present around the device region in a plan view. The first coil and the second coil are arranged on the device region and are arranged in a first direction in a plan view. The third coil and the fourth coil are respectively opposed to the first coil and the second coil via the insulating layer. The first shield is arranged between the semiconductor substrate and the first and second coils and overlaps with the first coil and the second coil in a plan view. A width of the first shield in a second direction orthogonal to the first direction is larger than a width of the first coil in the second direction and a width of the second coil in the second direction. The first shield is electrically connected to a reference potential.

### CROSS-REFERENCE TO RELATED APPLICATIONS

The disclosure of Japanese Patent Application No. 2023-113612 filed on Jul. 11, 2023 including the specification, drawings and abstract is incorporated herein by reference in its entirety.

### BACKGROUND

This disclosure relates to a semiconductor device.

There are disclosed techniques listed below.
[Patent Document 1] International Publication No. 2014/097425

Patent Document 1 discloses a semiconductor device. The semiconductor device disclosed in Patent Document 1 has a plurality of transformers. Each transformer is composed of coils facing each other via an insulating layer. Each of the plurality of transformers forms a channel for transmitting and receiving signals.

### SUMMARY

In the semiconductor device described in Patent Document 1, crosstalk may occur between channels. Other problems and novel features will become apparent from the description of this specification and the accompanying drawings.

A semiconductor device of this disclosure includes a semiconductor substrate, a first coil, a second coil, a third coil, and a fourth coil, an insulating layer, and a first shield. The semiconductor substrate has a device region and a peripheral region. The peripheral region is present around the device region in a plan view. The first coil and the second coil are arranged on the device region and are arranged in a first direction in a plan view. The third coil and the fourth coil are respectively opposed to the first coil and the second coil via the insulating layer. The first shield is arranged between the semiconductor substrate and the first and second coils and overlaps with the first coil and the second coil in a plan view. A width of the first shield in a second direction orthogonal to the first direction is larger than a width of the first coil in the second direction and a width of the second coil in the second direction. The first shield is electrically connected to a reference potential.

According to the semiconductor device of this disclosure, crosstalk between channels can be suppressed.

### BRIEF DESCRIPTION OF THE DRAWINGS

FIG. 1 is a block diagram of a semiconductor device DEV1.

FIG. 2 is an explanatory diagram showing an example of signal transmission from a control circuit CC to a drive circuit DR.

FIG. 3 is a first plan view of a semiconductor chip CHP3.

FIG. 4 is a second plan view of the semiconductor chip CHP3.

FIG. 5 is a third plan view of the semiconductor chip CHP3.

FIG. 6A is a cross-sectional view taken along the line VIA-VIA in FIG. 5.

FIG. 6B is a cross-sectional view taken along the line VIB-VIB in FIG. 5.

FIG. 7 is a manufacturing process diagram of the semiconductor chip CHP3.

FIG. 8 is a cross-sectional view for describing an ion implantation step S2.

FIG. 9 is a cross-sectional view for describing a first insulating film formation step S3.

FIG. 10 is a cross-sectional view for describing a first via plug formation step S4.

FIG. 11 is a cross-sectional view for describing a shield formation step S5.

FIG. 12 is a cross-sectional view for describing a second insulating film formation step S6.

FIG. 13 is a cross-sectional view for describing a second via plug formation step S7.

FIG. 14 is a cross-sectional view for describing a first coil formation step S8.

FIG. 15 is a cross-sectional view for describing a third insulating film formation step S9.

FIG. 16 is a cross-sectional view for describing a third via plug formation step S10.

FIG. 17 is a cross-sectional view for describing a wiring formation step S11.

FIG. 18 is a cross-sectional view for describing a second coil formation step S12.

FIG. 19 is a plan view of a semiconductor chip CHP3 in a semiconductor device DEV2.

FIG. 20 is a plan view of a semiconductor chip CHP3 in a semiconductor device DEV3.

FIG. 21 is a plan view of a semiconductor chip CHP3 in a semiconductor device DEV4.

FIG. 22 is a plan view of a semiconductor chip CHP3 in a semiconductor device DEV5.

FIG. 23 is a cross-sectional view taken along the line XXIII-XXIII in FIG. 22.

FIG. 24 is a plan view of a semiconductor chip CHP3 in a semiconductor device DEV6.

FIG. 25 is a cross-sectional view taken along the line XXV-XXV in FIG. 24.

FIG. 26 is a cross-sectional view of a semiconductor chip CHP3 according to a modification of the semiconductor device DEV6.

### DETAILED DESCRIPTION

The embodiments of this disclosure will be described with reference to the drawings. In the following drawings, the same or equivalent components are denoted by the same reference characters, and overlapping descriptions will not be repeated.

### First Embodiment

A semiconductor device according to the first embodiment will be described. The semiconductor device according to the first embodiment is referred to as a semiconductor device DEV1.

### (Configuration of Semiconductor Device DEV1)

The configuration of the semiconductor device DEV1 will be described below.

### <General Configuration of Semiconductor Device DEV1>

The general configuration of the semiconductor device DEV1 will be described below.

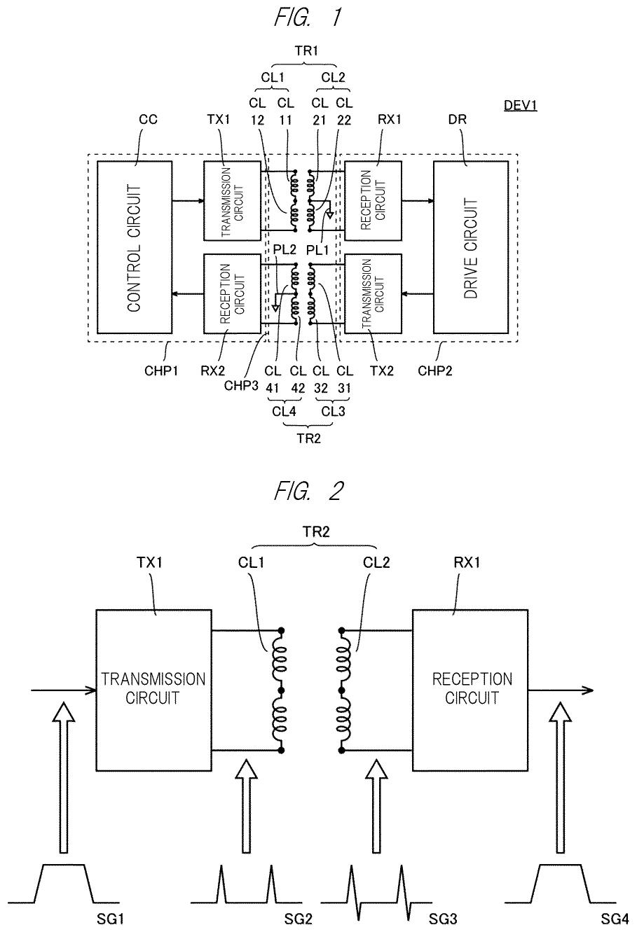

FIG. 1 is a block diagram of the semiconductor device DEV1. As shown in FIG. 1, the semiconductor device DEV1 includes semiconductor chips CHP1, CHP2, and CHP3.

The semiconductor chip CHP1 includes a control circuit CC, a transmission circuit TX1, and a reception circuit RX2. The semiconductor chip CHP2 includes a drive circuit DR, a reception circuit RX1, and a transmission circuit TX2. The transmission circuit TX1 and the reception circuit RX2 are electrically connected to the control circuit CC. The reception circuit RX1 and the transmission circuit TX2 are electrically connected to the drive circuit DR.

The semiconductor chip CHP3 includes transformers TR1 and TR2 and lead wires PL1 and PL2.

The transformer TR1 includes a transmission coil CL1 and a reception coil CL2. The transmission coil CL1 includes a coil CL11 and a coil CL12, and the reception coil CL2 includes a coil CL21 and a coil CL22. The transmission coil CL1 and the reception coil CL2 are electrically connected to the transmission circuit TX1 and the reception circuit RX1, respectively.

More specifically, one end of the coil CL11 is electrically connected to the transmission circuit TX1, the other end of the coil CL11 is electrically connected to one end of the coil CL12, and the other end of the coil CL12 is electrically connected to the transmission circuit TX1. Also, one end of the coil CL21 is electrically connected to the reception circuit RX1, the other end of the coil CL21 is electrically connected to one end of the coil CL22 through the lead wire PL1, and the other end of the coil CL22 is electrically connected to the reception circuit RX1. The lead wire PL1 is connected to a reference potential. Note that the reference potential is, for example, a ground potential.

The transformer TR2 includes a transmission coil CL3 and a reception coil CL4. The transmission coil CL3 includes a coil CL31 and a coil CL32, and the reception coil CL4 includes a coil CL41 and a coil CL42. The transmission coil CL3 and the reception coil CL4 are electrically connected to the transmission circuit TX2 and the reception circuit RX2, respectively.

More specifically, one end of the coil CL31 is electrically connected to the transmission circuit TX2, the other end of the coil CL31 is electrically connected to one end of the coil CL32, and the other end of the coil CL32 is electrically connected to the transmission circuit TX2. Also, one end of the coil CL41 is electrically connected to the reception circuit RX2, the other end of the coil CL41 is electrically connected to one end of the coil CL42 through the lead wire PL2, and the other end of the coil CL42 is electrically connected to the reception circuit RX2. The lead wire PL2 is connected to the reference potential.

In the semiconductor device DEV1, a signal is transmitted from the control circuit CC to the drive circuit DR by the transmission circuit TX1, the transformer TR1, and the reception circuit RX1. Also, in the semiconductor device DEV1, a signal is transmitted from the drive circuit DR to the control circuit CC by the transmission circuit TX2, the transformer TR2, and the reception circuit RX2.

FIG. 2 is an explanatory diagram showing an example of signal transmission from the control circuit CC to the drive circuit DR. As shown in FIG. 2, the control circuit CC inputs a signal SG1 to the transmission circuit TX1. The signal SG1 is a square wave. The transmission circuit TX1 modulates the signal SG1 to a signal SG2 and sends the signal SG2 to the transmission coil CL1. When the signal SG2 flows into the transmission coil CL1, a signal SG3 corresponding to the signal SG2 flows into the reception coil CL2 by induced electromotive force. The reception circuit RX1 amplifies the signal SG3 and demodulates it to a signal SG4 (square wave), and then outputs it to the drive circuit DR. In this way, the signal is transmitted from the control circuit CC to the drive circuit DR. Note that signal transmission from the drive circuit DR to the control circuit CC is also performed in the same way. Thus, in the semiconductor device DEV1, signal transmission between the transmission circuit TX1 and the reception circuit RX1 and signal transmission between the transmission circuit TX2 and the reception circuit RX2 are performed by a pulse communication method.

### <Detailed Configuration of Semiconductor Chip CHP3>

The detailed configuration of the semiconductor chip CHP3 will be described below.

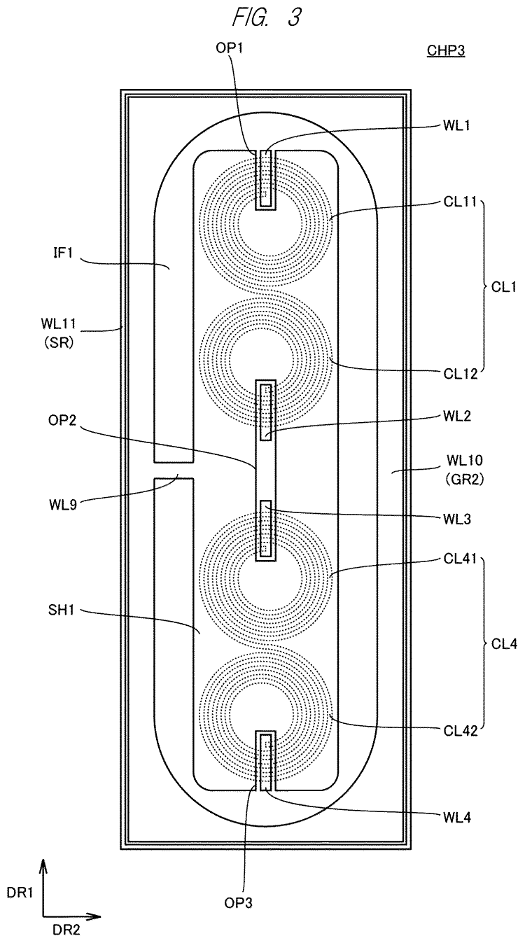

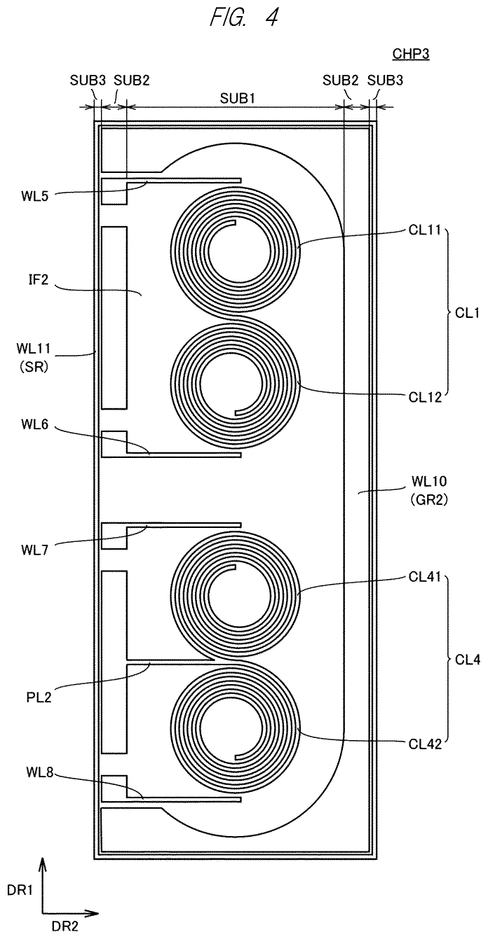

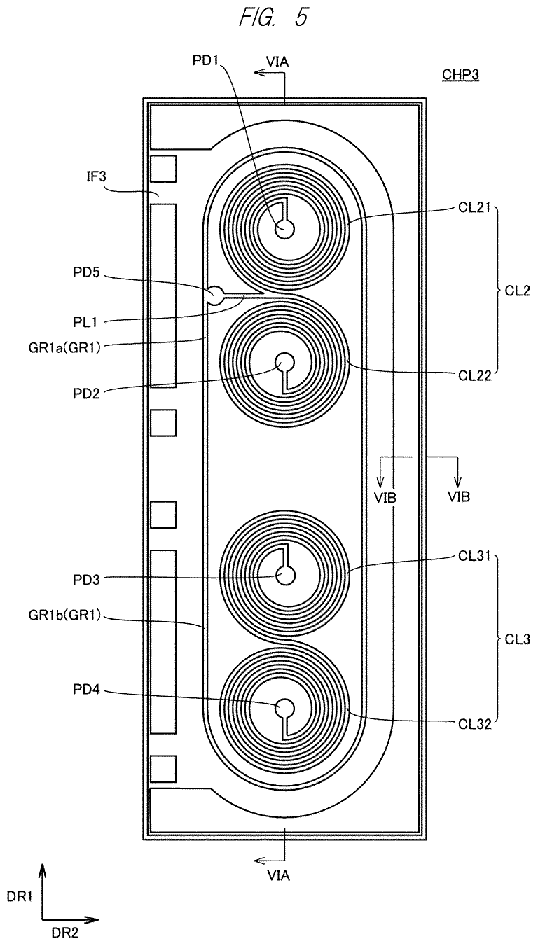

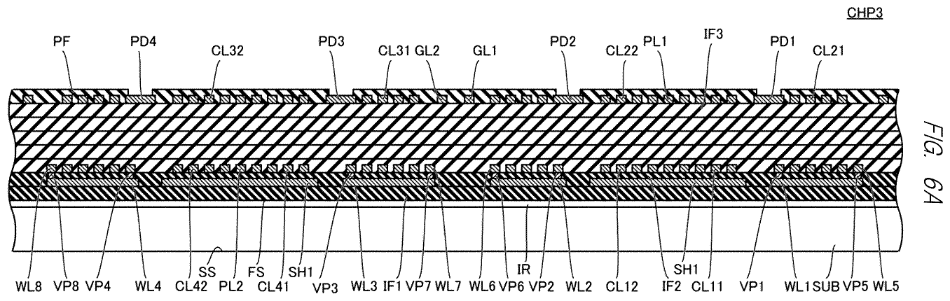

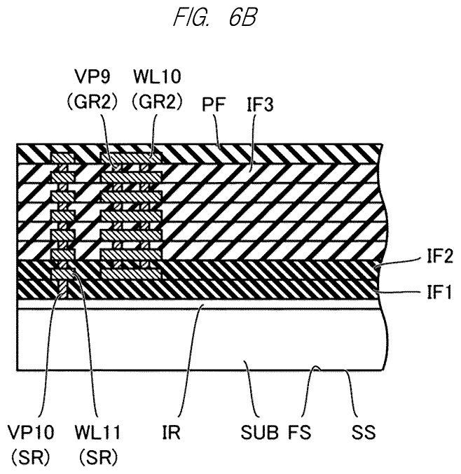

FIG. 3 is a first plan view of the semiconductor chip CHP3. FIG. 4 is a second plan view of the semiconductor chip CHP3. FIG. 5 is a third plan view of the semiconductor chip CHP3. FIG. 6A is a cross-sectional view taken along the line VIA-VIA in FIG. 5. FIG. 6B is a cross-sectional view taken along the line VIB-VIB in FIG. 5. As shown in FIG. 3 to FIG. 6B, the semiconductor chip CHP3 includes a semiconductor substrate SUB, an insulating film IF1, a shield SH1, a wiring WL1, a wiring WL2, a wiring WL3, and a wiring WL4, an insulating film IF2, a via plug VP1, a via plug VP2, a via plug VP3, a via plug VP4, a via plug VP5, a via plug VP6, a via plug VP7, and a via plug VP8, the transmission coil CL1, the reception coil CL4, a wiring WL5, a wiring WL6, a wiring WL7, and a wiring WL8, and the lead wire PL2.

The semiconductor chip CHP3 further includes a plurality of insulating films IF3, the reception coil CL2, the lead wire PL1, the transmission coil CL3, a pad PD1, a pad PD2, a pad PD3, a pad PD4, and a pad PD5, and a guard ring GR1. The semiconductor chip CHP3 further includes a guard ring GR2, a seal ring SR, a wiring WL9, and a passivation film PF.

The semiconductor substrate SUB has a first surface FS and a second surface SS. The first surface FS and the second surface SS are end surfaces in the thickness direction of the semiconductor substrate SUB. The second surface SS is the opposite surface of the first surface FS. The constituent material of the semiconductor substrate SUB is, for example, single-crystal silicon. The semiconductor substrate SUB has an impurity implantation region IR. The impurity implantation region IR is formed in the first surface FS. The impurity implantation region IR may be formed in the entire first surface FS, or may be partially formed in the first surface FS. The conductivity type of the semiconductor substrate SUB is, for example, p-type. The dopant concentration in the impurity implantation region IR is higher than the dopant concentration outside the impurity implantation region IR.

The semiconductor substrate SUB has a device region SUB1, a peripheral region SUB2, and an outer peripheral region SUB3 in a plan view. The peripheral region SUB2 is present around the device region SUB1 and surrounds the device region SUB1. The outer peripheral region SUB3 is present in an outer edge of the semiconductor substrate SUB and surrounds the peripheral region SUB2.

The insulating film IF1 is arranged on the semiconductor substrate SUB. The constituent material of the insulating film IF1 is, for example, silicon oxide.

The shield SH1 is arranged on the insulating film IF1. The shield SH1 is arranged on the device region SUB1. The outer shape of the shield SH1 in a plan view is generally rectangular. The constituent material of the shield SH1 is, for example, aluminum, aluminum alloy, copper, copper alloy, or the like. Namely, the constituent material of the shield SH1 is, for example, a conductive material containing aluminum as a main component or a conductive material containing copper as a main component. The term “main component” refers to a constituent element that accounts for more than 50 mass percent in the constituent material.

The shield SH1 has an opening OP1, an opening OP2, and an opening OP3. The openings OP1, OP2, and OP3 penetrate the shield SH1 in the thickness direction.

The wirings WL1, WL2, WL3, and WL4 are arranged on the insulating film IF1. The wiring WL1 is arranged inside the opening OP1 in a plan view. The wirings WL2 and WL3 are arranged inside the opening OP2 in a plan view. The wiring WL4 is arranged inside the opening OP3. The constituent material of the wirings WL1, WL2, WL3, and WL4 is, for example, a conductive material containing aluminum as a main component. The constituent material of the wirings WL1, WL2, WL3, and WL4 may be a conductive material containing copper as a main component.

The insulating film IF2 is arranged on the insulating film IF1 so as to cover the shield SH1 and the wirings WL1, WL2, WL3, and WL4. The constituent material of the insulating film IF2 is, for example, silicon oxide.

The via plugs VP1, VP2, VP3, VP4, VP5, VP6, VP7, and VP8 are embedded in the insulating film IF2. The constituent material of the via plugs VP1, VP2, VP3, VP4, VP5, VP6, VP7, and VP8 is, for example, a conductive material containing tungsten as a main component.

The transmission coil CL1 (coils CL11, CL12), the reception coil CL4 (coils CL41, CL42), and the lead wire PL2 are arranged on the insulating film IF2. In other words, the coils CL11, CL12, CL41, and CL42 and the lead wire PL2 are formed in the same layer on the semiconductor substrate SUB. The constituent material of the coils CL11, CL12, CL41, and CL42 and the lead wire PL2 is, for example, a conductive material containing aluminum as a main component. The constituent material of the coils CL11, CL12, CL41, and CL42 and the lead wire PL2 may be a conductive material containing copper as a main component.

In a plan view, the coils CL11, CL12, CL41, and CL42 are arranged in the first direction DR1. The coils CL12 and CL41 are adjacent to each other. The coil CL11 is adjacent to the coil CL12 from the opposite side of the coil CL41. The coil CL42 is adjacent to the coil CL41 from the opposite side of the coil CL12. The coils CL11, CL12, CL41, and CL42 are arranged on the device region SUB1.

In a plan view, the coils CL11 and CL12 are wound in a spiral shape. The coils CL11 and CL12 are electrically connected in series. More specifically, the end at the outermost periphery of the coil CL11 and the end at the outermost periphery of the coil CL12 are electrically connected to each other.

In a plan view, the coil CL11 is wound counterclockwise from the innermost periphery to the outermost periphery. In a plan view, the coil CL12 is wound clockwise from the outermost periphery to the innermost periphery. Namely, the winding direction of the coil CL11 may be opposite to the winding direction of the coil CL12. In other words, the coils CL11 and CL12 are in a serial aiding configuration.

In a plan view, the coils CL41 and CL42 are wound in a spiral shape. In a plan view, the coils CL41 and CL42 are adjacent to each other. The coils CL41 and CL42 are electrically connected in series. More specifically, the end at the outermost periphery of the coil CL41 and the end at the outermost periphery of the coil CL42 are electrically connected to each other. The lead wire PL2 is formed between the coil CL41 and the coil CL42.

In a plan view, the coil CL41 is wound counterclockwise from the innermost periphery to the outermost periphery. In a plan view, the coil CL42 is wound clockwise from the outermost periphery to the innermost periphery. Namely, the winding direction of the coil CL41 may be opposite to the winding direction of the coil CL42. In other words, the coils CL41 and CL42 are in a serial aiding configuration.

In a plan view, the coils CL11, CL12, CL41, and CL42 overlap with the shield SH1. Namely, the shield SH1 is arranged between the coils CL11, CL12, CL41, and CL42 and the semiconductor substrate SUB. The shield SH1 is continuously formed to span between the coil CL12 and the coil CL41 in a plan view.

The second direction DR2 is a direction orthogonal to the first direction DR1. The width of the shield SH1 in the second direction DR2 is larger than the width of the coil CL11 in the second direction DR2, the width of the coil CL12 in the second direction DR2, the width of the coil CL41 in the second direction DR2, and the width of the coil CL42 in the second direction DR2.

The wirings WL5, WL6, WL7, and WL8 are arranged on the insulating film IF2. The constituent material of the wirings WL5, WL6, WL7, and WL8 is, for example, a conductive material containing aluminum as a main component. The constituent material of the wirings WL5, WL6, WL7, and WL8 may be a conductive material containing copper as a main component.

The wiring WL5 is electrically connected to the wiring WL1 by the via plug VP5, and the wiring WL6 is electrically connected to the wiring WL2 by the via plug VP6. The wiring WL7 is electrically connected to the wiring WL3 by the via plug VP7, and the wiring WL8 is electrically connected to the wiring WL4 by the via plug VP8.

The plurality of insulating films IF3 are stacked on the insulating film IF2. The insulating film IF3 in the bottommost layer covers the coils CL11, CL12, CL41, and CL42, the lead wire PL2, and the wirings WL5, WL6, WL7, and WL8. The constituent material of the insulating film IF3 is, for example, silicon oxide.

The coils CL21, CL22, CL31, and CL32 are arranged on the insulating film IF3 in the topmost layer. The constituent material of the coils CL21, CL22, CL31, and CL32 is, for example, a conductive material containing aluminum as a main component. The constituent material of the coils CL21, CL22, CL31, and CL32 may be a conductive material containing copper as a main component.

The coils CL21 and CL22 are respectively opposed to the coils CL11 and CL12 via the plurality of insulating films IF3. In other words, the coils CL21 and CL22 overlap with the coils CL11 and CL12 in a plan view. From another perspective, the coils CL21 and CL22 are magnetically coupled to the coils CL11 and CL12, respectively.

The coils CL21 and CL22 are wound in a spiral shape in a plan view. The coils CL21 and CL22 are adjacent to each other in a plan view. The coils CL21 and CL22 are electrically connected in series. More specifically, the end at the outermost periphery of the coil CL21 and the end at the outermost periphery of the coil CL22 are electrically connected to each other. The lead wire PL1 is formed between the coil CL21 and the coil CL22.

In a plan view, the coil CL21 is wound counterclockwise from the innermost periphery to the outermost periphery. In a plan view, the coil CL22 is wound clockwise from the outermost periphery to the innermost periphery. Namely, the winding direction of the coil CL21 may be opposite to the winding direction of the coil CL22. In other words, the coils CL21 and CL22 are in a serial aiding configuration.

The coils CL31 and CL32 are respectively opposed to the coils CL41 and CL42 via the plurality of insulating films IF3. In other words, the coils CL31 and CL32 overlap with the coils CL41 and CL42 in a plan view. From another perspective, the coils CL31 and CL32 are magnetically coupled to the coils CL41 and CL42, respectively.

The coils CL31 and CL32 are wound in a spiral shape in a plan view. The coils CL31 and CL32 are adjacent to each other in a plan view. The coils CL31 and CL32 are electrically connected in series. More specifically, the end at the outermost periphery of the coil CL31 and the end at the outermost periphery of the coil CL32 are electrically connected to each other.

The coil CL31 is wound counterclockwise from the innermost periphery to the outermost periphery in a plan view. The coil CL32 is wound clockwise from the outermost periphery to the innermost periphery in a plan view. Namely, the winding direction of the coil CL31 may be opposite to the winding direction of the coil CL32. In other words, the coils CL31 and CL32 are in a serial aiding configuration.

The distance between the coil CL11 and the coil CL21 or between the coil CL12 and the coil CL22 may be, for example, 6 μm or more and 14 μm or less. The distance between the coil CL41 and the coil CL31 or between the coil CL42 and the coil CL32 is, for example, 6 μm or more and 14 μm or less.

The pads PD1, PD2, PD3, PD4, and PD5 are arranged on the insulating film IF3 in the topmost layer. The pad PD1 is connected to the end of the innermost periphery of the coil CL21, and the pad PD2 is connected to end of the innermost periphery of the coil CL22. The pad PD3 is connected to end of the innermost periphery of the coil CL31, and the pad PD4 is connected to the end of the innermost periphery of the coil CL32. The pad PD5 is connected to the end of the lead wire PL1 on the opposite side of the coils CL21 and CL22. The constituent material of the pads PD1, PD2, PD3, PD4, and PD5 is, for example, a conductive material containing aluminum as a main component. The constituent material of the pads PD1, PD2, PD3, PD4, and PD5 may be a conductive material containing copper as a main component.

The guard ring GR1 is arranged on the insulating film IF3 in the topmost layer. The guard ring GR1 has a first portion GR1a and a second portion GR1b. The first portion GR1a surrounds the reception coil CL2 in a plan view, and the second portion GR1b surrounds the transmission coil CL3 in a plan view. The pad PD5 is in contact with the guard ring GR1 (first portion GR1a). Therefore, the guard ring GR1 is connected to the reference potential in the same way as the lead wire PL1. The constituent material of the guard ring GR1 is, for example, a conductive material containing aluminum as a main component. The constituent material of the guard ring GR1 may be a conductive material containing copper as a main component.

The guard ring GR2 has a plurality of wirings WL10 and a plurality of via plugs VP9. The wirings WL10 are arranged on each of the insulating film IF1, the insulating film IF2, and the plurality of insulating films IF3. In other words, the shield SH1 is formed in the same layer as the wiring WL10 in the bottommost layer. The via plugs VP9 are embedded in each of the insulating film IF2 and the plurality of insulating films IF3. The wirings WL10 and the via plugs VP9 are alternately stacked on the peripheral region SUB2. The guard ring GR2 (more specifically, the wiring WL10 in the topmost layer) is connected to the reference potential.

The constituent material of the wiring WL10 is, for example, a conductive material containing aluminum as a main component. The constituent material of the wiring WL10 may be a conductive material containing copper as a main component. The constituent material of the via plug VP9 is, for example, a conductive material containing tungsten as a main component.

The wiring WL9 is arranged on the insulating film IF1. The wiring WL9 is connected at one end to the shield SH1 and connected at the other end to the wiring WL10 in the bottommost layer. As a result, the shield SH1 is connected to the reference potential. The constituent material of the wiring WL9 is, for example, a conductive material containing aluminum as a main component. The constituent material of the wiring WL9 may be a conductive material containing copper as a main component.

The seal ring SR has a plurality of wirings WL11 and a plurality of via plugs VP10. The wirings WL11 are arranged on each of the insulating film IF1, the insulating film IF2, and the plurality of insulating films IF3. The via plugs VP10 are embedded in each of the insulating film IF1, the insulating film IF2, and the plurality of insulating films IF3. The wirings WL11 and the via plugs VP10 are alternately stacked on the outer peripheral region SUB3. Since the via plug VP10 is also embedded in the insulating film IF1, the seal ring SR is electrically connected to the semiconductor substrate SUB (more specifically, the impurity implantation region IR). The reference potential is connected to the seal ring SR (more specifically, the wiring WL11 in the topmost layer). Therefore, the semiconductor substrate SUB is also connected to the reference potential.

The constituent material of the wiring WL11 is, for example, a conductive material containing aluminum as a main component. The constituent material of the wiring WL11 may be a conductive material containing copper as a main component. The constituent material of the via plug VP10 is, for example, a conductive material containing tungsten as a main component.

The passivation film PF is arranged on the insulating film IF3 in the topmost layer so as to cover the reception coil CL2 (coils CL21, CL22), the transmission coil CL3 (coils CL31, CL32), the lead wire PL1, the pads PD1, PD2, PD3, PD4, and PD5, the guard ring GR1, the wiring WL10 in the topmost layer, and the wiring WL11 in the topmost layer. Note that the pads PD1, PD2, PD3, PD4, and PD5 are exposed from the opening of the passivation film PF. The constituent material of the passivation film PF is, for example, silicon nitride.

### <Manufacturing Method of Semiconductor Chip CHP3>

The manufacturing method of the semiconductor chip CHP3 will be described below.

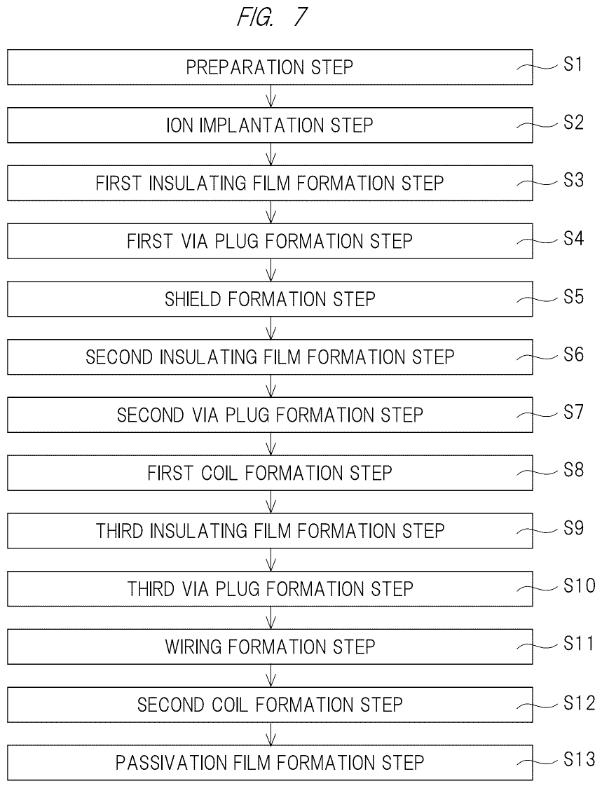

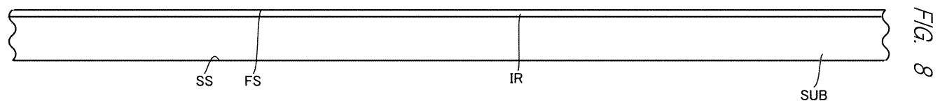

FIG. 7 is a manufacturing process diagram of the semiconductor chip CHP3. As shown in FIG. 7, the manufacturing method of the semiconductor chip CHP3 includes a preparation step S1, an ion implantation step S2, a first insulating film formation step S3, a first via plug formation step S4, a shield formation step S5, a second insulating film formation step S6, a second via plug formation step S7, a first coil formation step S8, a third insulating film formation step S9, a third via plug formation step S10, a wiring formation step S11, a second coil formation step S12, and a passivation film formation step S13.

In the preparation step S1, the semiconductor substrate SUB is prepared. After the preparation step S1, the ion implantation step S2 is performed. FIG. 8 is a cross-sectional view for describing the ion implantation step S2. As shown in FIG. 8, in the ion implantation step S2, the impurity implantation region IR is formed by ion implantation. After the ion implantation step S2, the first insulating film formation step S3 is performed.

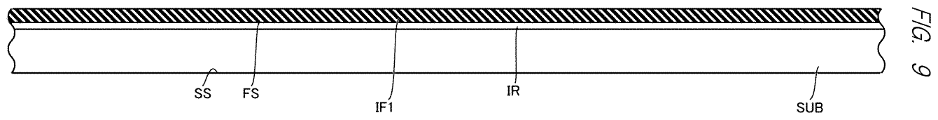

FIG. 9 is a cross-sectional view for describing the first insulating film formation step S3. In the first insulating film formation step S3, the insulating film IF1 is formed on the semiconductor substrate SUB by, for example, the CVD (Chemical Vapor Deposition) method. After the first insulating film formation step S3, the first via plug formation step S4 is performed.

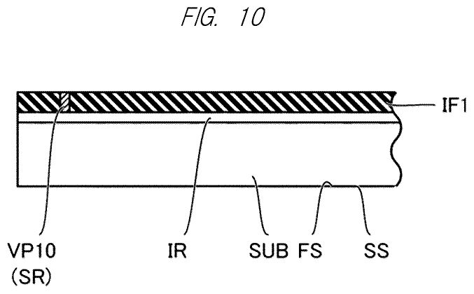

FIG. 10 is a cross-sectional view for describing the first via plug formation step S4. As shown in FIG. 10, in the first via plug formation step S4, the via plug VP10 is embedded in the insulating film IF1. In the first via plug formation step S4, first, a via hole is formed in the insulating film IF1 by the dry etching using a resist pattern formed by photolithography as a mask. Second, the constituent material of the via plug VP10 is embedded in the via hole by, for example, the CVD method. Third, the constituent material of the via plug VP10 that protrudes from the via hole is removed by, for example, the CMP (Chemical Mechanical Polishing) method. After the first via plug formation step S4, the shield formation step S5 is performed.

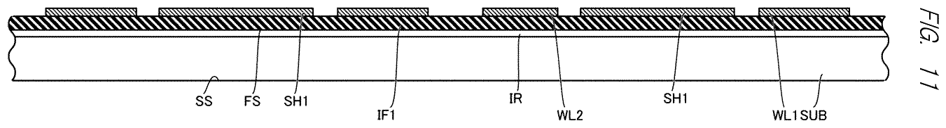

FIG. 11 is a cross-sectional view for describing the shield formation step S5. As shown in FIG. 11, in the shield formation step S5, the shield SH1 is formed on the insulating film IF1. In the shield formation step S5, first, the constituent material of the shield SH1 is deposited by, for example, the sputtering method. Second, the deposited constituent material of the shield SH1 is patterned by, for example, the dry etching using a resist pattern formed by photolithography as a mask. In the shield formation step S5, the wirings WL1, WL2, WL3, and WL4 are also formed in the same manner. Although not shown, in the shield formation step S5, the wirings WL9, WL10, and WL11 are also formed in the same manner. After the shield formation step S5, the second insulating film formation step S6 is performed.

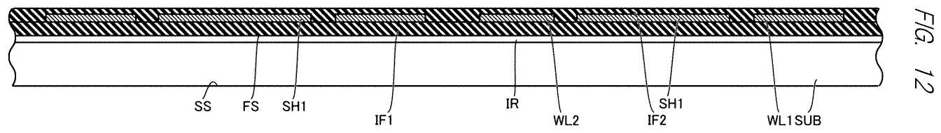

FIG. 12 is a cross-sectional view for describing the second insulating film formation step S6. As shown in FIG. 12, in the second insulating film formation step S6, the insulating film IF2 is formed on the insulating film IF1 so as to cover the shield SH1 and the wirings WL1, WL2, WL3, WL4, WL9 (not shown in FIG. 12), WL10 (not shown in FIG. 12), and WL11 (not shown in FIG. 12). In the second insulating film formation step S6, first, the constituent material of the insulating film IF2 is deposited by, for example, the CVD method. Second, the constituent material of the deposited insulating film IF2 is flattened by, for example, the CMP method. After the second insulating film formation step S6, the second via plug formation step S7 is performed.

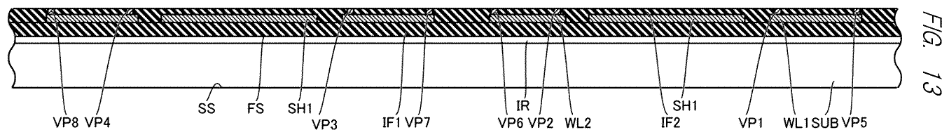

FIG. 13 is a cross-sectional view for describing the second via plug formation step S7. As shown in FIG. 13, in the second via plug formation step S7, the via plugs VP1, VP2, VP3, VP4, VP5, VP6, VP7, and VP8 are embedded in the insulating film IF2 by the same method as the first via plug formation step S4. Although not shown, the via plugs VP9 and VP10 are also formed in the same way in the second via plug formation step S7. After the second via plug formation step S7, the first coil formation step S8 is performed.

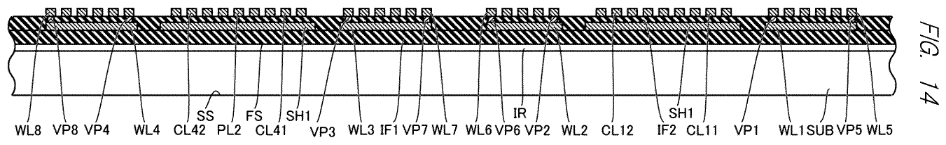

FIG. 14 is a cross-sectional view for describing the first coil formation step S8. As shown in FIG. 14, in the first coil formation step S8, the transmission coil CL1 and the reception coil CL4 are formed on the insulating film IF2. In the first coil formation step S8, first, the constituent materials of the transmission coil CL1 and the reception coil CL4 are deposited by, for example, the sputtering method. Second, the deposited constituent materials of the transmission coil CL1 and the reception coil CL4 are patterned by, for example, the dry etching using a resist pattern formed by photolithography as a mask. In the first coil formation step S8, the wirings WL5, WL6, WL7, and WL8 and the lead wire PL2 are also formed in the same way. Although not shown, the wirings WL10 and WL11 are also formed in the same way in the first coil formation step S8. After the first coil formation step S8, the third insulating film formation step S9 is performed.

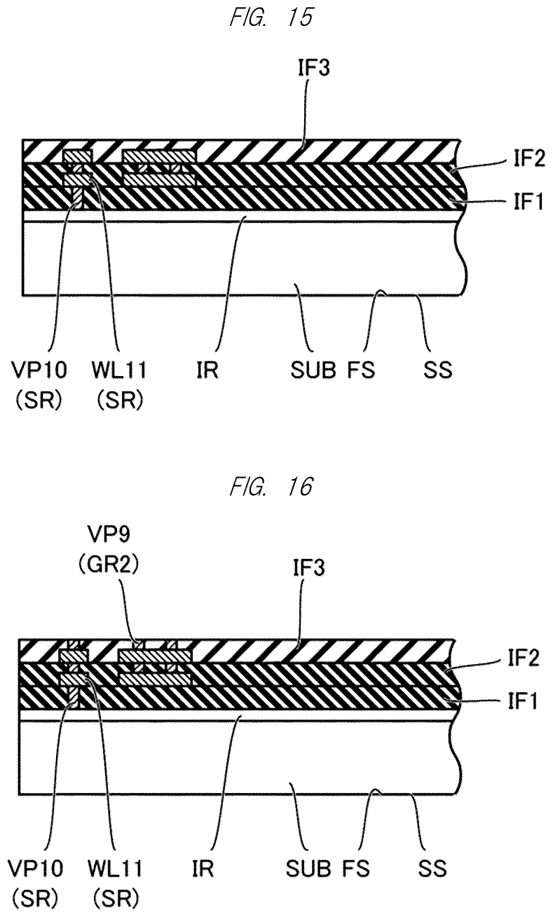

FIG. 15 is a cross-sectional view for describing the third insulating film formation step S9. As shown in FIG. 15, in the third insulating film formation step S9, the insulating film IF3 is formed on the insulating film IF2 by the same method as the second insulating film formation step S6 so as to cover the transmission coil CL1, the reception coil CL4, the lead wire PL2, and the wirings WL5, WL6, WL7, WL8 (that are not shown in FIG. 15), WL10, and WL11. After the third insulating film formation step S9, the third via plug formation step S10 is performed.

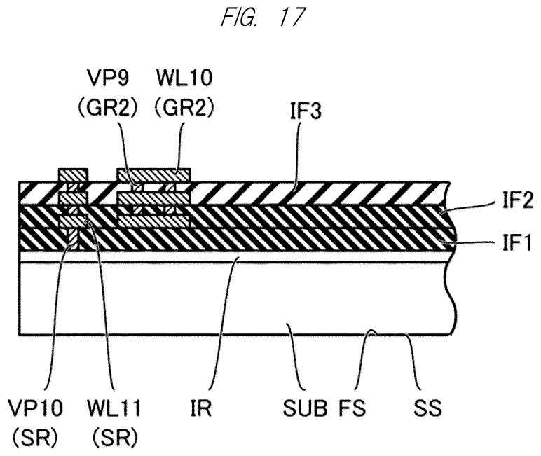

FIG. 16 is a cross-sectional view for describing the third via plug formation step S10. As shown in FIG. 16, in the third via plug formation step S10, the via plugs VP9 and VP10 are embedded in the insulating film IF3 by the same method as the second via plug formation step S7. After the third via plug formation step S10, the wiring formation step S11 is performed. FIG. 17 is a cross-sectional view for describing the wiring formation step S11. As shown in FIG. 17, in the wiring formation step S11, the wirings WL10 and WL11 are formed by the same method as the first coil formation step S8. The third insulating film formation step S9, the third via plug formation step S10, and the wiring formation step S11 are repeated until the insulating film IF3 in the topmost layer is formed. After the insulating film IF3 in the topmost layer is formed, the second coil formation step S12 is performed.

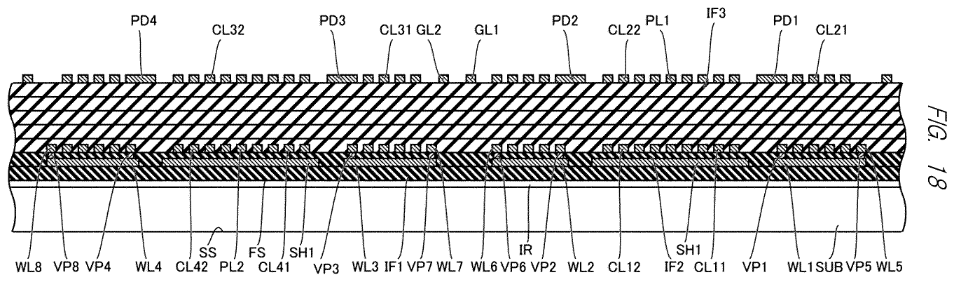

FIG. 18 is a cross-sectional view for describing the second coil formation step S12. As shown in FIG. 18, in the second coil formation step S12, the reception coil CL2, the transmission coil CL3, the lead wire PL1, the pads PD1 to PD5, the guard ring GR1, and the wirings WL10 (not shown in FIG. 18) and WL11 (not shown in FIG. 18) are formed on the insulating film IF3 in the topmost layer by the same method as the first coil formation step S8. After the second coil formation step S12, the passivation film formation step S13 is performed.

In the passivation film formation step S13, the passivation film PF is formed on the insulating film IF3 in the topmost layer so as to cover the reception coil CL2, the transmission coil CL3, the lead wire PL1, the pads PD1 to PD5, the guard ring GR1, and the wirings WL10 and WL11. In the passivation film formation step S13, first, the constituent material of the passivation film PF is deposited by, for example, the CVD method. Second, the constituent material of the passivation film PF is patterned by, for example, the dry etching using a resist pattern formed by photolithography as a mask.

After the above steps, dicing or the like is performed, whereby individual pieces of the semiconductor chip CHP3 having the structure shown in FIG. 3 to FIG. 6B are formed.

### <Effect of Semiconductor Device DEV1>

The effect of the semiconductor device DEV1 will be described below.

In the semiconductor device DEV1, the transformers TR1 and TR2 are consolidated in the semiconductor chip CHP3. Since no semiconductor elements such as transistors are formed in the semiconductor chip CHP3, it is possible to optimize the manufacturing process of the semiconductor chip CHP3 according to the transformers TR1 and TR2.

When the shield SH1 is not arranged, the insulating films IF1 and IF2 between the transmission coil CL1 (coils CL11, CL12) and the semiconductor substrate SUB constitute a capacitance. Similarly, the insulating films IF1 and IF2 between the reception coil CL4 (coils CL41, CL42) and the semiconductor substrate SUB constitute a capacitance. Since the above capacitance has a small impedance for high-frequency signals, the current flowing through one of the transmission coil CL1 and the reception coil CL4 flows through the capacitance and the semiconductor substrate SUB to the other of the transmission coil CL1 and the reception coil CL4, thereby causing crosstalk between channels.

Note that, if the impurity implantation region is formed on the entire first surface FS, since there is no need to form a mask in the ion implantation step S2, the process of forming the semiconductor chip CHP3 is simplified. However, if the impurity implantation region is formed on the entire first surface FS, since the electrical resistance of the semiconductor substrate SUB decreases, the current flowing through one of the transmission coil CL1 and the reception coil CL4 is likely to flow through the capacitance and the semiconductor substrate SUB to the other of the transmission coil CL1 and the reception coil CL4.

In the semiconductor device DEV1, since the shield SH1 connected to the reference potential is arranged between the transmission coil CL1 and the reception coil CL4, the capacitive coupling described above is unlikely to occur. Therefore, according to the semiconductor device DEV1, it is possible to suppress the crosstalk between channels.

### Second Embodiment

A semiconductor device according to the second embodiment will be described. The semiconductor device according to the second embodiment is referred to as a semiconductor device DEV2. Here, the points different from the semiconductor device DEV1 will be mainly described, and the overlapping descriptions will not be repeated.

### <Configuration of Semiconductor Device DEV2>

The configuration of the semiconductor device DEV2 will be described below.

The semiconductor device DEV2 includes the semiconductor chip CHP1, the semiconductor chip CHP2, and the semiconductor chip CHP3. In this regard, the configuration of the semiconductor device DEV2 is common to the configuration of the semiconductor device DEV1.

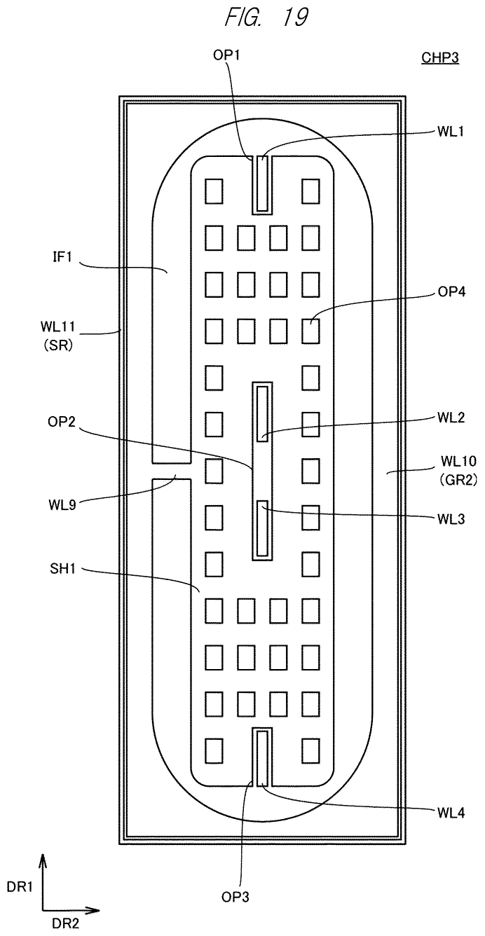

FIG. 19 is a plan view of the semiconductor chip CHP3 in the semiconductor device DEV2. As shown in FIG. 19, in the semiconductor device DEV2, a plurality of openings OP4 are formed in the shield SH1. The openings OP4 penetrate the shield SH1 in the thickness direction. The plurality of openings OP4 are arranged in, for example, a grid pattern in a plan view. The plurality of openings OP4 may be arranged in a checkerboard pattern. In a plan view, the length of the opening OP4 in the longitudinal direction is, for example, 50 μm or less. In these respects, the configuration of the semiconductor device DEV2 is different from the configuration of the semiconductor device DEV1.

### <Effect of Semiconductor Device DEV2>

The effect of the semiconductor device DEV2 will be described below.

An eddy current may flow in the shield SH1 due to the magnetic flux generated by a current flowing through the transmission coil CL1 (coils CL11, CL12) and the reception coil CL4 (coils CL41, CL42). However, since the openings OP4 are formed in the shield SH1 in the semiconductor device DEV2, the range in which the eddy current flows is limited by the openings OP4. Thus, it is possible to suppress the generation of the eddy current in the shield SH1 by the semiconductor device DEV2. Furthermore, even if the openings OP4 are formed, the shield SH1 can sufficiently suppress crosstalk between channels if the length of the opening OP4 in the longitudinal direction is 50 μm or less in a plan view.

### Third Embodiment

A semiconductor device according to the third embodiment will be described. The semiconductor device according to the third embodiment is referred to as a semiconductor device DEV3. Here, the points different from the semiconductor device DEV1 will be mainly described, and the overlapping descriptions will not be repeated.

### <Configuration of Semiconductor Device DEV3>

The configuration of the semiconductor device DEV3 will be described below.

The semiconductor device DEV3 includes the semiconductor chip CHP1, the semiconductor chip CHP2, and the semiconductor chip CHP3. In this regard, the configuration of the semiconductor device DEV3 is common to the configuration of the semiconductor device DEV1.

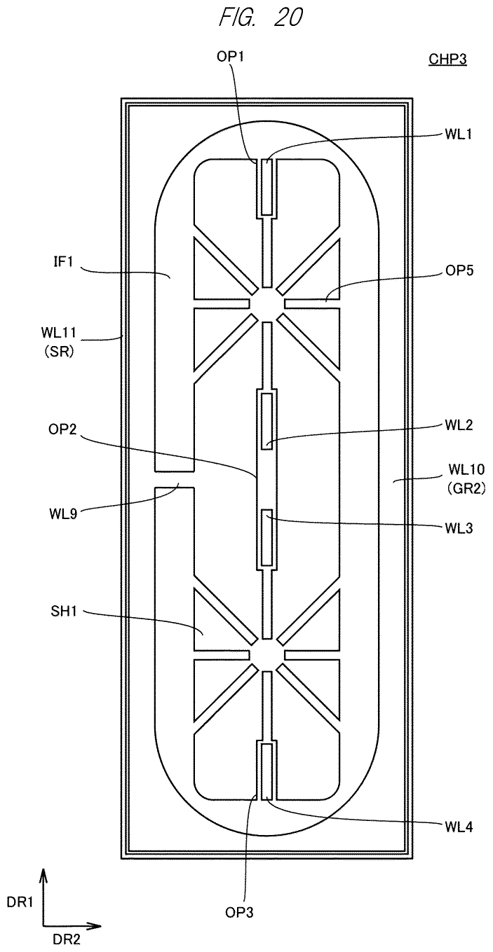

FIG. 20 is a plan view of the semiconductor chip CHP3 in the semiconductor device DEV3. As shown in FIG. 20, in the semiconductor device DEV3, a plurality of slit openings OP5 are formed in the shield SH1. The slit openings OP5 penetrate the shield SH1 in the thickness direction. For example, the plurality of slit openings OP5 are arranged radially in a plan view. In these respects, the configuration of the semiconductor device DEV3 is different from the configuration of the semiconductor device DEV1.

### <Effect of Semiconductor Device DEV3>

The effect of the semiconductor device DEV3 will be described below.

An eddy current may flow in the shield SH1 due to the magnetic flux generated by a current flowing through the transmission coil CL1 (coils CL11, CL12) and the reception coil CL4 (coils CL41, CL42). However, since the slit openings OP5 are formed in the shield SH1 in the semiconductor device DEV3, the range in which the eddy current flows is limited by the slit openings OP5. Thus, it is possible to suppress the generation of the eddy current in the shield SH1 by the semiconductor device DEV3.

### Fourth Embodiment

A semiconductor device according to the fourth embodiment will be described. The semiconductor device according to the fourth embodiment is referred to as a semiconductor device DEV4. Here, the points different from the semiconductor device DEV1 will be mainly described, and the overlapping descriptions will not be repeated.

### <Configuration of Semiconductor Device DEV4>

The configuration of the semiconductor device DEV4 will be described below.

The semiconductor device DEV4 includes the semiconductor chip CHP1, the semiconductor chip CHP2, and the semiconductor chip CHP3. In this regard, the configuration of the semiconductor device DEV4 is common to the configuration of the semiconductor device DEV1.

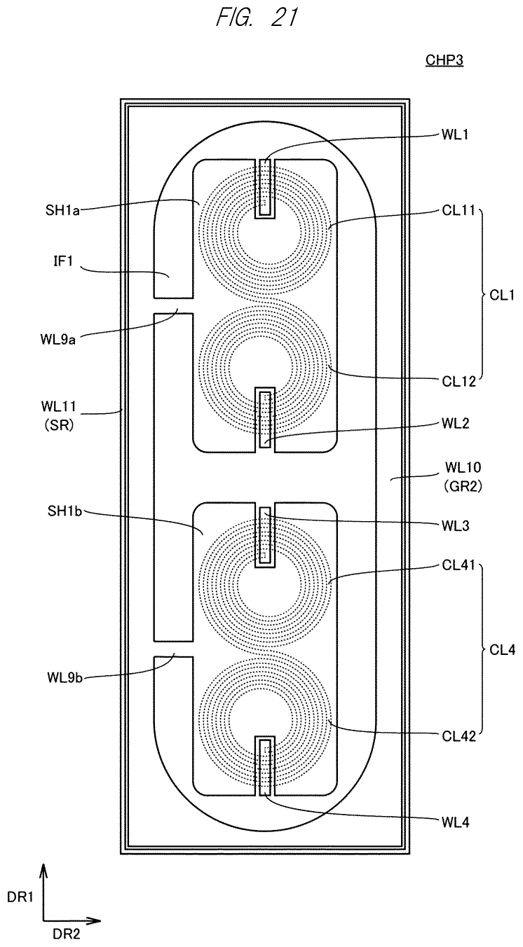

FIG. 21 is a plan view of the semiconductor chip CHP3 in the semiconductor device DEV4. As shown in FIG. 21, in the semiconductor device DEV4, the shield SH1 is formed separately between the coil CL12 and the coil CL41 in a plan view. Namely, in the semiconductor device DEV4, the shield SH1 has a first portion SH1a overlapping with the transmission coil CL1 in a plan view and a second portion SH1b overlapping with the reception coil CL4 in a plan view.

In the semiconductor device DEV4, the semiconductor chip CHP3 has a wiring WL9a and a wiring WL9b instead of the wiring WL9. The wiring WL9a is connected at one end to the first portion SH1a and connected at the other end to the wiring WL10. As a result, the first portion SH1a is connected to the reference potential. The wiring WL9b is connected at one end to the second portion SH1b and connected at the other end to the wiring WL10. As a result, the second portion SH1b is connected to the reference potential. In these respects, the configuration of the semiconductor device DEV4 is different from the configuration of the semiconductor device DEV1.

### <Effect of Semiconductor Device DEV4>

The effect of the semiconductor device DEV4 will be described below.

The insulating film IF2 between the transmission coil CL1 (coils CL11, CL12) and the shield SH1 constitutes a capacitance. Similarly, the insulating film IF2 between the reception coil CL4 (coils CL41, CL42) and the shield SH1 also constitutes a capacitance. Therefore, the high-frequency current flowing in one of the transmission coil CL1 and the reception coil CL4 flows through the above-mentioned capacitance and the shield SH1 to the other of the transmission coil CL1 and the reception coil CL4, thereby causing crosstalk between channels in some cases.

Since the shield SH1 is formed separately between the transmission coil CL1 and the reception coil CL4 (between coil CL12 and coil CL41) in a plan view in the semiconductor device DEV4, the above-mentioned current is unlikely to flow from one of the transmission coil CL1 and the reception coil CL4 to the other of the transmission coil CL1 and the reception coil CL4. Therefore, according to the semiconductor device DEV4, it is possible to further suppress crosstalk between channels.

### Fifth Embodiment

A semiconductor device according to the fifth embodiment will be described. The semiconductor device according to the fifth embodiment is referred to as a semiconductor device DEV5. Here, the points different from the semiconductor device DEV1 will be mainly described, and the overlapping descriptions will not be repeated.

### <Configuration of Semiconductor Device DEV5>

The configuration of the semiconductor device DEV5 will be described below.

The semiconductor device DEV5 includes the semiconductor chip CHP1, the semiconductor chip CHP2, and the semiconductor chip CHP3. In this regard, the configuration of the semiconductor device DEV5 is common to the configuration of the semiconductor device DEV1.

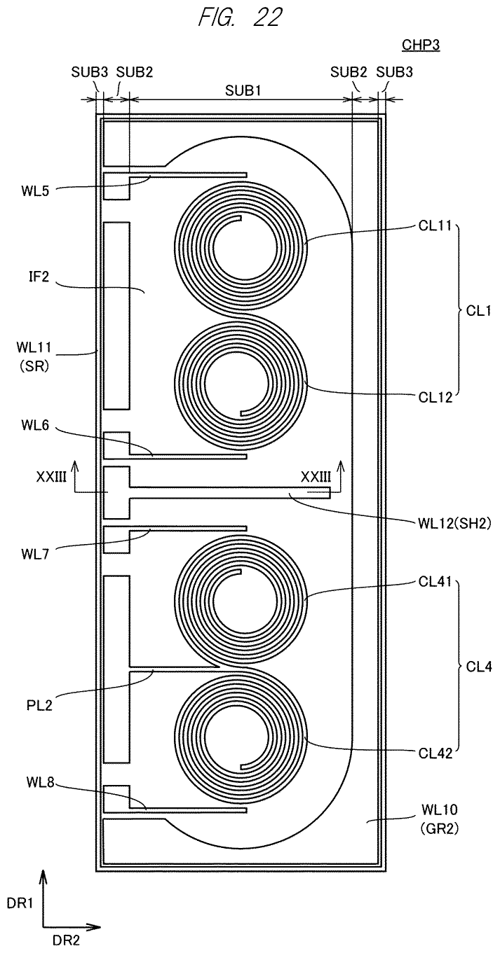

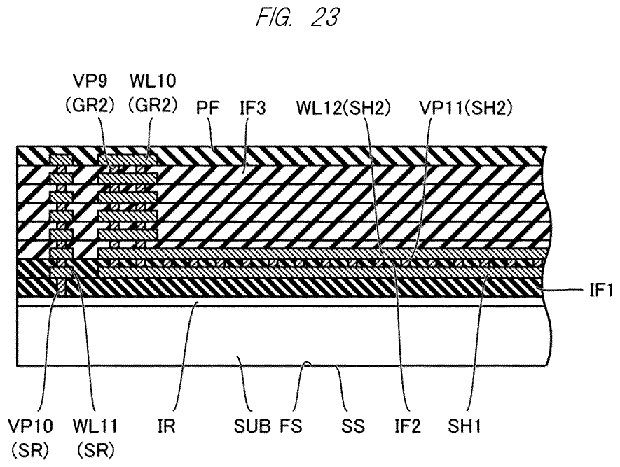

FIG. 22 is a plan view of the semiconductor chip CHP3 in the semiconductor device DEV5. FIG. 23 is a cross-sectional view taken along the line XXIII-XXIII in FIG. 22. As shown in FIG. 22 and FIG. 23, the semiconductor device DEV5 includes a shield SH2 and a plurality of via plugs VP11.

In a plan view, the shield SH2 is arranged between the transmission coil CL1 and the reception coil CL4. More specifically, in a plan view, the shield SH2 is arranged between the coil CL12 and the coil CL41. The shield SH2 is composed of, for example, a wiring WL12 and the via plug VP11.

The wiring WL12 is arranged on the insulating film IF2. Namely, the wiring WL12 is formed in the same layer as the transmission coil CL1 (coils CL11, CL12) and the reception coil CL4 (coils CL41, CL42). In a plan view, the wiring WL12 extends in the second direction DR2. The constituent material of the wiring WL12 is a conductive material containing aluminum as a main component. The constituent material of the wiring WL12 may be a conductive material containing copper as a main component. The via plug VP11 is embedded in the insulating film IF2. In a plan view, the plurality of via plugs VP11 are arranged at intervals in the second direction DR2. The constituent material of the via plug VP11 is a conductive material containing tungsten as a main component.

The width of the wiring WL12 in the second direction DR2 is larger than the width of the coil CL12 in the second direction DR2 and the width of the coil CL41 in the second direction DR2. For example, the wiring WL12 is connected to the wiring WL10 arranged on the insulating film IF2. Also, the via plug VP11 electrically connects the wiring WL12 and the shield SH1. Therefore, the shield SH2 is electrically connected to the reference potential.

The shortest distance between the lower layer coil (transmission coil CL1, reception coil CL4) and the upper layer coil (reception coil CL2, transmission coil CL3) is defined as a first distance. The shortest distance between the upper layer coil and the shield SH2 (wiring WL12) is defined as a second distance. In order to ensure the withstand voltage between the lower layer coil and the upper layer coil, the second distance is larger than the first distance. In these regards, the configuration of the semiconductor device DEV5 is common to the configuration of the semiconductor device DEV1.

Note that the via plug VP11 is formed in the second via plug formation step S7, and the wiring WL12 is formed in the first coil formation step S8.

### <Effect of Semiconductor Device DEV5>

The effect of the semiconductor device DEV5 will be described below.

Since the transmission coil CL1 and the reception coil CL4 are adjacent to each other, the electromagnetic waves generated by the current flowing through one of the transmission coil CL1 and the reception coil CL4 interfere with the other of the transmission coil CL1 and the reception coil CL4, thereby causing crosstalk between channels in some cases. In the semiconductor device DEV5, the shield SH2 which is electrically connected to the reference potential is arranged between the transmission coil CL1 and the reception coil CL4 in a plan view. Therefore, according to the semiconductor device DEV5, the shield SH2 functions as a Faraday shield, and it is possible to suppress the occurrence of the above-mentioned crosstalk between channels.

In the semiconductor device DEV5, since the constituent material of the shield SH2 (the constituent material of the wiring WL12, the constituent material of the via plug VP11) is a metal material with low electrical resistance and the electrons induced by the electromagnetic waves are quickly discharged from the shield SH2, the shield SH2 effectively functions as a Faraday shield.

### Sixth Embodiment

A semiconductor device according to the sixth embodiment will be described. The semiconductor device according to the sixth embodiment is referred to as a semiconductor device DEV6. Here, the points different from the semiconductor device DEV5 will be mainly described, and the overlapping descriptions will not be repeated.

### <Configuration of Semiconductor Device DEV6>

The configuration of the semiconductor device DEV6 will be described below.

The semiconductor device DEV6 includes the semiconductor chip CHP1, the semiconductor chip CHP2, and the semiconductor chip CHP3. In this regard, the configuration of the semiconductor device DEV6 is common to the configuration of the semiconductor device DEV5.

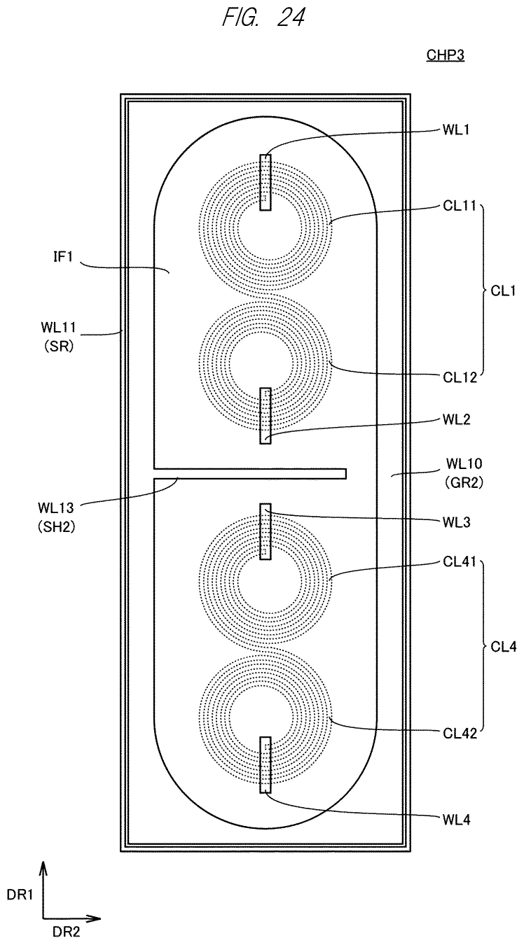

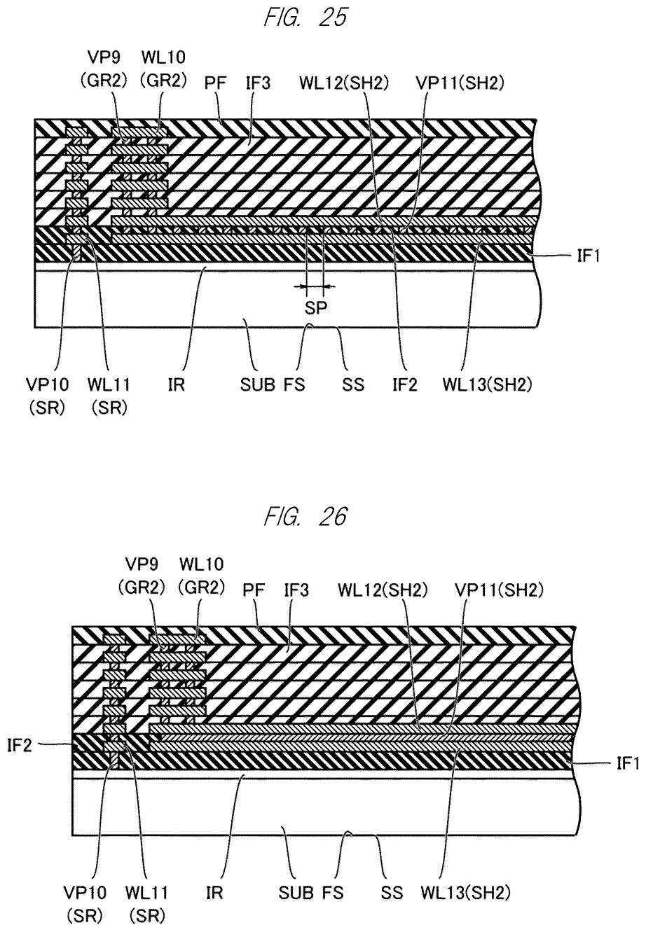

FIG. 24 is a plan view of the semiconductor chip CHP3 in the semiconductor device DEV6. FIG. 25 is a cross-sectional view taken along the line XXV-XXV in FIG. 24. As shown in FIG. 24 and FIG. 25, the semiconductor device DEV6 does not have the shield SH1.

In the semiconductor device DEV6, the shield SH2 is composed of the wiring WL12, a wiring WL13, and the via plug VP11. Namely, the shield SH2 is composed of the wiring formed in the same layer as the wiring WL10 located on the insulating film IF1, the wiring formed in the same layer as the wiring WL10 located on the insulating film IF2, and the via plug between these wirings. The wiring WL13 extends in the second direction DR2 in a plan view. The wiring WL13 is arranged on the insulating film IF1. In a plan view, the wiring WL13 overlaps with the wiring WL12. The constituent material of the wiring WL13 is, for example, a conductive material containing aluminum as a main component. The constituent material of the wiring WL13 is a conductive material containing copper as a main component. In the semiconductor device DEV6, the wiring WL13 is formed instead of the shield SH1 in the shield formation step S5.

The wiring WL12 and the wiring WL13 are electrically connected by the plurality of via plugs VP11. Also, the wiring WL13 is connected to the wiring WL10 on the insulating film IF1. Namely, the wiring WL12 and the wiring WL13 are stacked via the plurality of via plugs VP11. Therefore, the shield SH2 is connected to the reference potential. Since the plurality of via plugs VP11 are arranged at intervals, the wiring WL12 and the wiring WL13 are connected in a dot via structure. The interval between two adjacent via plugs VP11 is defined as an interval SP. The interval SP is, for example, 0.3 μm or more and 2 μm or less. In these respects, the configuration of the semiconductor device DEV6 is different from the configuration of the semiconductor device DEV5.

### Modification

FIG. 26 is a cross-sectional view of the semiconductor chip CHP3 according to a modification of the semiconductor device DEV6. FIG. 26 shows a cross-section at a position corresponding to the line IIV-IIV in FIG. 24. As shown in FIG. 26, the number of via plugs VP11 may be one. In this case, the via plug VP11 is continuously formed in the direction in which the wiring WL12 and the wiring WL13 extend in a plan view. In other words, the wiring WL12 and the wiring WL13 may be connected in a slit via structure.

### <Effect of Semiconductor Device DEV6>

The effect of the semiconductor device DEV6 will be described below.

In the semiconductor device DEV6 as well, since the shield SH2 which is electrically connected to the reference potential is arranged between the transmission coil CL1 and the reception coil CL4 in a plan view, the shield SH2 functions as a Faraday shield, and it is possible to suppress the occurrence of crosstalk between channels. If the interval SP is 2 μm or less, the interval SP is smaller than the wavelength of the electromagnetic waves generated by the transmission coil CL1 and the reception coil CL4, and it is thus possible to sufficiently suppress the occurrence of crosstalk between channels. When the via plug VP11 is continuously formed in the direction in which the wiring WL12 and the wiring WL13 extend, there is no gap between adjacent via plugs VP11, and it is thus possible to further suppress the occurrence of crosstalk between channels.

### (Additional Statement)

The above embodiments include the following configurations.

### <Additional Statement 1>

A semiconductor device comprising:
a first semiconductor chip;
a second semiconductor chip; and
a third semiconductor chip,
wherein the first semiconductor chip has a first transmission circuit and a first reception circuit,
wherein the second semiconductor chip has a second transmission circuit and a second reception circuit,
wherein the third semiconductor chip has a semiconductor substrate, a first coil, a second coil, a third coil, a fourth coil, an insulating layer, and a first shield,
wherein the semiconductor substrate has a device region and a peripheral region,
wherein the peripheral region is present around the device region in a plan view,
wherein the first coil and the second coil are arranged on the device region and are arranged in a first direction in a plan view,
wherein the third coil and the fourth coil are respectively opposed to the first coil and the second coil via the insulating layer,
wherein the first shield is arranged between the semiconductor substrate and the first and second coils, and overlaps with the first coil and the second coil in a plan view,
wherein a width of the first shield in a second direction orthogonal to the first direction is larger than a width of the first coil in the second direction and a width of the second coil in the second direction,
wherein the first shield is electrically connected to a reference potential,
wherein a signal transmitted from the first transmission circuit is transmitted to the second reception circuit via the first coil and the third coil, and
wherein a signal transmitted from the second transmission circuit is transmitted to the first reception circuit via the fourth coil and the second coil.

### <Additional Statement 2>

The semiconductor device according to Additional Statement 1,
wherein a signal transmission method from the first transmission circuit to the second reception circuit and a signal transmission method from the second transmission circuit to the first reception circuit are pulse communication methods.

### <Additional Statement 3>

The semiconductor device according to Additional Statement 1,
wherein the first shield is continuously formed so as to span between the first coil and the second coil in a plan view.

### <Additional Statement 4>

The semiconductor device according to Additional Statement 1,
wherein the first shield has a plurality of openings, and
wherein the plurality of openings are arranged in a grid or checkered pattern in a plan view.

### <Additional Statement 5>

The semiconductor device according to Additional Statement 4,
wherein a length of the opening in a longitudinal direction is 50 μm or less in a plan view.

### <Additional Statement 6>

The semiconductor device according to Additional Statement 1,
wherein the first shield has a plurality of slit openings, and
wherein the plurality of slit openings are arranged radially in a plan view.

### <Additional Statement 7>

The semiconductor device according to Additional Statement 1,
wherein the first shield is formed separately between the first coil and the second coil in a plan view.

### <Additional Statement 8>

The semiconductor device according to Additional Statement 1, further comprising a second shield arranged between the first coil and the second coil in a plan view,
wherein a width of the second shield in the second direction is larger than the width of the first coil in the second direction and the width of the second coil in the second direction, and
wherein the second shield is electrically connected to the reference potential.

### <Additional Statement 9>

The semiconductor device according to Additional Statement 8,
wherein the first shield is electrically connected to the second shield and is electrically connected to the reference potential via the second shield.

### <Additional Statement 10>

The semiconductor device according to Additional Statement 8,
wherein the second shield is spaced apart from the first coil and the second coil in a plan view, and
wherein a distance between the first coil and the second shield and a distance between the second coil and the second shield are 12 μm or more and 100 μm or less in a plan view.

### <Additional Statement 11>

The semiconductor device according to Additional Statement 8,
wherein the second shield has a plurality of first via plugs and a first wiring and a second wiring stacked via the plurality of first via plugs, and
wherein an interval between two adjacent first via plugs of the plurality of first via plugs is 0.3 μm or more and 2 μm or less.

### <Additional Statement 12>

The semiconductor device according to Additional Statement 8,
wherein the second shield has a first via plug and a first wiring and a second wiring stacked via the first via plug, and
wherein the first via plug is continuously formed along a direction in which the first wiring and the second wiring extend.

### <Additional Statement 13>

The semiconductor device according to Additional Statement 8,
wherein the second shield has at least one first via plug and a first wiring and a second wiring stacked via the at least one first via plug,
wherein a constituent material of the first via plug is a conductive material containing tungsten as a main component, and
wherein a constituent material of the first wiring and a constituent material of the second wiring are conductive materials containing aluminum or copper as a main component.

### <Additional Statement 14>

The semiconductor device according to Additional Statement 1,
wherein a constituent material of the first shield is a conductive material containing aluminum or copper as a main component.

### <Additional Statement 15>

The semiconductor device according to Additional statement 1, further comprising a lead wire formed in the same layer as the first shield and connected to the first shield.

### <Additional Statement 16>

The semiconductor device according to Additional statement 8, further comprising a guard ring arranged on the peripheral region,
wherein the guard ring has a plurality of wirings and a plurality of second via plugs,
wherein the wirings and the second via plugs are alternately stacked,
wherein the plurality of wirings include a third wiring in a bottommost layer and a fourth wiring located in an upper layer of the third wiring,
wherein the first shield is formed in the same layer as the third wiring, and
wherein the second shield is formed in the same layer as the third wiring, the fourth wiring, and the second via plug located between the third wiring and the fourth wiring.

### <Additional Statement 17>

The semiconductor device according to Additional Statement 1,
wherein a distance between the first coil and the third coil or a distance between the second coil and the fourth coil is 6 μm or more and 14 μm or less.

### <Additional Statement 18>

The semiconductor device according to Additional Statement 1,
wherein the first coil and the third coil are magnetically coupled to each other, and
wherein the second coil and the fourth coil are magnetically coupled to each other.

In the foregoing, the invention made by the inventors of this application has been concretely described based on the embodiments. However, it is needless to say that the present invention is not limited to the foregoing embodiments and various modifications can be made within the range not departing from the gist thereof.

What is claimed is:

1. A semiconductor device comprising:
a semiconductor substrate;
a first coil, a second coil, a third coil, and a fourth coil;
an insulating layer; and
a first shield,
wherein the semiconductor substrate has a device region and a peripheral region,
wherein the peripheral region is present around the device region in a plan view,
wherein the first coil and the second coil are arranged on the device region and are arranged in a first direction in a plan view,
wherein the third coil and the fourth coil are respectively opposed to the first coil and the second coil via the insulating layer,
wherein the first shield is arranged between the semiconductor substrate and the first and second coils and overlaps with the first coil and the second coil in a plan view,
wherein a width of the first shield in a second direction orthogonal to the first direction is larger than a width of the first coil in the second direction and a width of the second coil in the second direction, and
wherein the first shield is electrically connected to a reference potential.

2. The semiconductor device according to claim 1,
wherein the first shield is continuously formed so as to span between the first coil and the second coil in a plan view.

3. The semiconductor device according to claim 1,
wherein the first shield has a plurality of openings, and
wherein the plurality of openings are arranged in a grid or checkerboard pattern in a plan view.

4. The semiconductor device according to claim 3,
wherein a length of the opening in a longitudinal direction is 50 μm or less in a plan view.

5. The semiconductor device according to claim 1,
wherein the first shield has a plurality of slit openings, and
wherein the plurality of slit openings are arranged radially in a plan view.

6. The semiconductor device according to claim 1,
wherein the first shield is formed separately between the first coil and the second coil in a plan view.

7. The semiconductor device according to claim 1, further comprising a second shield arranged between the first coil and the second coil in a plan view,
wherein a width of the second shield in the second direction is larger than the width of the first coil in the second direction and the width of the second coil in the second direction, and
wherein the second shield is electrically connected to the reference potential.

8. The semiconductor device according to claim 7,
wherein the first shield is electrically connected to the second shield and is electrically connected to the reference potential via the second shield.

9. The semiconductor device according to claim 7,
wherein the second shield is spaced apart from the first coil and the second coil in a plan view, and
wherein a distance between the first coil and the second shield and a distance between the second coil and the second shield are 12 μm or more and 100 μm or less in a plan view.

10. The semiconductor device according to claim 7,
wherein the second shield has a plurality of first via plugs and a first wiring and a second wiring stacked via the plurality of first via plugs, and
wherein an interval between two adjacent first via plugs of the plurality of first via plugs is 0.3 μm or more and 2 μm or less.

11. The semiconductor device according to claim 7,
wherein the second shield has a first via plug and a first wiring and a second wiring stacked via the first via plug, and
wherein the first via plug is continuously formed along a direction in which the first wiring and the second wiring extend.

12. The semiconductor device according to claim 7,
wherein the second shield has at least one first via plug and a first wiring and a second wiring stacked via the at least one first via plug,
wherein a constituent material of the first via plug is a conductive material containing tungsten as a main component, and
wherein a constituent material of the first wiring and a constituent material of the second wiring are conductive materials containing aluminum or copper as a main component.

13. The semiconductor device according to claim 1,
wherein a constituent material of the first shield is a conductive material containing aluminum or copper as a main component.

14. The semiconductor device according to claim 1, further comprising a lead wire formed in the same layer as the first shield and connected to the first shield.

15. The semiconductor device according to claim 7, further comprising a guard ring arranged on the peripheral region,
wherein the guard ring has a plurality of wirings and a plurality of second via plugs,
wherein the wirings and the second via plugs are alternately stacked,
wherein the plurality of wirings include a third wiring in a bottommost layer and a fourth wiring located in an upper layer of the third wiring,
wherein the first shield is formed in the same layer as the third wiring, and
wherein the second shield is formed in the same layer as the third wiring, the fourth wiring, and the second via plug located between the third wiring and the fourth wiring.

16. The semiconductor device according to claim 1,
wherein a distance between the first coil and the third coil or a distance between the second coil and the fourth coil is 6 μm or more and 14 μm or less in a plan view.

17. The semiconductor device according to claim 1,
wherein the first coil and the third coil are magnetically coupled to each other, and
wherein the second coil and the fourth coil are magnetically coupled to each other.

18. A semiconductor device comprising:
a semiconductor substrate;
a first coil, a second coil, a third coil, a fourth coil, a fifth coil, a sixth coil, a seventh coil, and an eighth coil;
an insulating layer; and
a first shield,
wherein the semiconductor substrate has a device region and a peripheral region,
wherein the peripheral region is present around the device region in a plan view,
wherein the first coil, the second coil, the fifth coil, and the sixth coil are arranged on the device region and are arranged in a first direction in a plan view,
wherein the first coil and the second coil are adjacent to each other,
wherein the fifth coil is adjacent to the first coil from an opposite side of the second coil, and is electrically connected in series to the first coil,
wherein the sixth coil is adjacent to the second coil from an opposite side of the first coil, and is electrically connected in series to the second coil,
wherein the third coil, the fourth coil, the seventh coil, and the eighth coil are respectively opposed to the first coil, the second coil, the fifth coil, and the sixth coil via the insulating layer,
wherein the seventh coil is electrically connected in series to the third coil,
wherein the eighth coil is electrically connected in series to the fourth coil,
wherein the first shield is arranged between the semiconductor substrate and the first, second, fifth, and sixth coils, and overlaps with the first coil, the second coil, the fifth coil, and the sixth coil in a plan view,
wherein a width of the first shield in a second direction orthogonal to the first direction is larger than a width of the first coil in the second direction, a width of the second coil in the second direction, a width of the fifth coil in the second direction, and a width of the sixth coil in the second direction, and
wherein the first shield is electrically connected to a reference potential.

19. The semiconductor device according to claim 18 further comprising a second shield arranged between the first coil and the second coil in a plan view,
wherein a width of the second shield in the second direction is larger than the width of the first coil in the second direction, the width of the second coil in the second direction, the width of the fifth coil in the second direction, and the width of the sixth coil in the second direction, and
wherein the second shield is electrically connected to the reference potential.
